(19) United States
(12) Patent Application Publication
(10) Pub. No.: US 2026/0009867 A1
(43) Pub. Date: Jan. 8, 2026

(54) SHUNT RESISTOR DEVICE, MONITORING DEVICE FOR SHUNT RESISTOR DEVICE, AND STORAGE MEDIUM

(71) Applicant: DENSO CORPORATION, Kariya-city (JP)

(72) Inventors: Hayato MIZOGUCHI, Kariya-city (JP); Ryosuke Sakai, Kariya-city (JP)

(73) Assignee: DENSO CORPORATION, Kariya-city (JP)

(21) Appl. No.: 19/326,274

(22) Filed: Sep. 11, 2025

Related U.S. Application Data
(63) Continuation of application No. PCT/JP2024/008749, filed on Mar. 7, 2024.

(30) Foreign Application Priority Data
Mar. 20, 2023 (JP) 2023-044735

(51) Int. Cl. G01R 31/66; G01R 19/165

(52) U.S. Cl. CPC G01R 31/66; G01R 19/16566

(57) ABSTRACT

A shunt resistor device includes: a plate-shaped resistor, a first electrode and a second electrode connected to respective ends of the resistor respectively in the first direction along the plate surface of the resistor; and a substrate having pairs of voltage detection points provided on the first and second electrode sides, and stacked on the resistor and each electrode. Each of the space between the resistor and each electrode, and the space between each electrode and the substrate, is joined by a conductive joint along a second direction orthogonal to the first direction. A monitoring device measures a terminal voltage between the first and second electrode sides of the resistor based on detection voltage between the pair of voltage detection points, and a fault detection unit of the monitoring device determines whether a joint abnormality of conductive joint occurs based on detection voltages of the first and second detection points.

### CROSS-REFERENCE TO RELATED APPLICATIONS

The present application is a continuation application of International Application No. PCT/JP2024/008749 filed on Mar. 7, 2024, which claims priority to Japanese application No. 2023-044735 filed on Mar. 20, 2023. The contents of these applications are incorporated herein by reference in their entirety.

### BACKGROUND

### 1. Technical Field

The present disclosure is related to a shunt resistor device, a monitoring device for a shunt resistor device, and a storage medium.

### 2. Related Art

A shunt resistor device described in JP2021182579A includes a resistor, a first electrode and a second electrode connected to respective ends of the resistor, and a substrate laminated on the upper surface thereof. The substrate is provided with a first through hole located above the first electrode and a second through hole located above the second electrode. The first through hole and the second through hole are filled with solder, and the substrate is joined to the first electrode and the second electrode by the solder. The solder filled in the first through hole and the second through hole is used as a voltage detection terminal to detect the terminal voltage of the resistor.

### SUMMARY

The present disclosure provides a monitoring device for a shunt resistor device. The shunt resistor device includes: a plate-shaped resistor, a first electrode and a second electrode connected to respective ends of the resistor respectively in the first direction along the plate surface of the resistor, and a substrate having pairs of voltage detection points provided on the first electrode side and the second electrode side, respectively, and stacked on the resistor and each electrode. Each of the space between the resistor and each electrode, and the space between each electrode and the substrate, is joined by a conductive joint along a second direction orthogonal to the first direction. The monitoring device measures a terminal voltage between the first electrode side and the second electrode side of the resistor based on the detection voltage between the pair of voltage detection points. The substrate includes, as the pairs of voltage detection points, first detection points and second detection points, the second detection points being positioned on the end side of each electrode relative to the first detection points in the second direction. The monitoring device includes a fault detection unit that determines whether a joint abnormality of the conductive joint occurs based on the detection voltages of the first detection points and the second detection point.

According to the present disclosure, the resistor of the shunt resistor device is joined to each electrode by the conductive joints, and through the conductive joints, current flows in the order of the first electrode, the resistor, and second electrode, or in the reverse order, generally along the first direction. The current flowing through each electrode and the resistor has a lower current density in the central area of the second direction of each electrode and a higher current density in the end area. Additionally, each electrode of the shunt resistor device is connected to the substrate via conductive joint, and current flows through the conductive joint between the first detection points and the first electrode provided in the substrate, and current flows through the conductive joint between the second detection points and the second electrode provided in the substrate. In the shunt resistor device of the present disclosure, in substrate, the second detection points are positioned on the end side of each electrode relative to the first detection points in the second direction. That is, the second detection points are positioned on the end side where the current density of the current flowing between each electrode and resistor is higher than that of the first detection point. Therefore, when there is no joint abnormality in conductive joint, the detection voltage in the first detection points differs from the detection voltage in the second detection point. When a joint abnormality occurs in conductive joint, the difference between the detection voltage in the first detection points and the detection voltage in the second detection points changes. The monitoring device according to the present disclosure includes a fault detection unit that determines whether a joint abnormality of the conductive joint occurs based on the detection voltages of the first detection points and the second detection point, thereby enabling, for example, monitoring the difference between the detection voltage in the first detection points and the detection voltage in the second detection points to detect conductive joint abnormalities.

The present disclosure also provides a shunt resistor device that detection of joint abnormality is possible. The shunt resistor device includes: a plate-shaped resistor, a first electrode and a second electrode connected to respective ends of the resistor respectively in the first direction along the plate surface of the resistor, and a substrate having pairs of voltage detection points provided on the first electrode side and the second electrode side, respectively, and stacked on the resistor and each electrode. Each of the space between the resistor and each electrode, and the space between each electrode and the substrate, is joined by a conductive joint along a second direction orthogonal to the first direction. The substrate includes, as the pairs of voltage detection points, first detection points and second detection points, the second detection points being positioned on the end side of each electrode relative to the first detection points in the second direction.

The present disclosure may also be provided as a monitoring program for the above-mentioned shunt resistor device. This monitoring program causes a computer to perform: a detection step for measuring a terminal voltage between the first electrode side and the second electrode side of the resistor based on the detection voltage between the pair of voltage detection point, and a fault detection step for determining whether a joint abnormality of the conductive joint occurs based on the detection voltages of the first detection points and the second detection point.

### BRIEF DESCRIPTION OF THE DRAWING

The above objectives and other objectives, features, and advantages of the present disclosure will become clearer with reference to the accompanying drawings and the detailed description below. The drawings are as follows:

FIG. 1 is a block diagram of a shunt resistor device and a monitoring device included in a power supply system according to a first embodiment;

FIG. 2 is an exploded view of the shunt resistor device according to the first embodiment;

FIG. 3 is an upper surface diagram of the shunt resistor device according to the first embodiment;

FIG. 4 is a cross-sectional view taken along the IV-IV line of FIG. 3;

FIG. 5 is a cross-sectional view taken along the V-V line of FIG. 3;

FIG. 6 is a current density distribution diagram of a current flowing between each electrode and resistor of the shunt resistor device according to the first embodiment;

FIG. 7 is a diagram showing the detected voltages in the first detection points and the second detection points;

FIG. 8 is a flowchart showing a monitoring process of the shunt resistor device according to the first embodiment;

FIG. 9 is a flowchart showing a monitoring method of the shunt resistor device according to the modified embodiment;

FIG. 10 is an upper surface diagram of the shunt resistor device according to a second embodiment;

FIG. 11 is an upper surface diagram showing a resistor and each electrode of the shunt resistor device according to the second embodiment;

FIG. 12 is a cross-sectional view taken along the XII-XII line in FIG. 11;

FIG. 13 is an upper surface diagram of a shunt resistor device according to a third embodiment;

FIG. 14 is an upper surface diagram of a shunt resistor device according to a fourth embodiment; and

FIG. 15 is a flowchart showing a monitoring process of the shunt resistor device according to the fourth embodiment.

### DETAILED DESCRIPTION OF THE PREFERRED EMBODIMENTS

By heat generated by a current flowing through a shunt resistor device may result in bonding abnormalities in a conductive joint such as solder. When conductivity between the substrate, and the first electrode and the second electrode is via solder as described in JP2021182579A, joint abnormalities in the solder may reduce the conductive area, thereby lowering the detection accuracy in resistor's terminal voltage.

In view of the above problem, the present disclosure aims to provide a technology capable of monitoring abnormalities in a conductive joint of a shunt resistor.

### First Embodiment

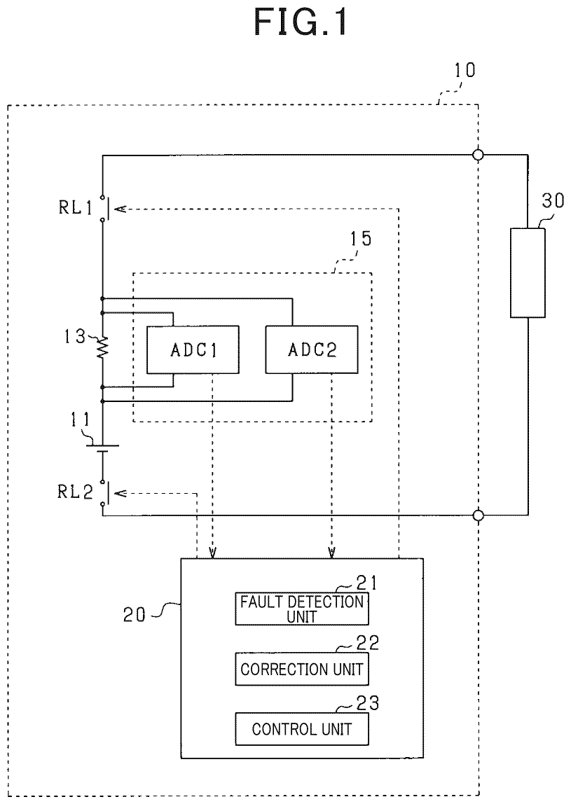

FIG. 1 shows a power supply system 10 including a monitoring device 20 of a resistor device 13 according to a first embodiment. The power supply system 10 has a battery 11, a resistor device 13, a detection circuit 15, a monitoring device 20, a first relay RL1, and a second relay RL2. As shown in FIG. 1, the resistor device 13 is connected to the high-potential side of the battery 11, the first relay RL1 is connected to the high-potential side of the resistor device 13, and the second relay RL2 is connected to the low-potential side of the battery 11. However, the connection order is not limited to this. For example, the battery 11 may be connected between the first relay RL1 and the resistor device 13. The power supply system 10 is connected to a load 30. The power supply system 10 is mounted to a vehicle, and the load 30 is various electrical loads on the vehicle.

The detection circuit 15 has a first AD converter ADC1 and a second AD converter ADC2 connected in parallel to the resistor device 13. When the first relay RL1 and the second relay RL2 are in the closed state, the resistor device 13 is energized. The monitoring device 20 acquires the terminal voltage of the resistor device 13 from the detection circuit 15. The monitoring device 20 acquires a first voltage V1 as a detected voltage from the first AD converter ADC1 and a second voltage V2 as a detected voltage from the second AD converter ADC2. The resistor device 13 is a shunt resistor device, and the monitoring device 20 detects a current flowing through the battery 11 by detecting the terminal voltage of the resistor device 13.

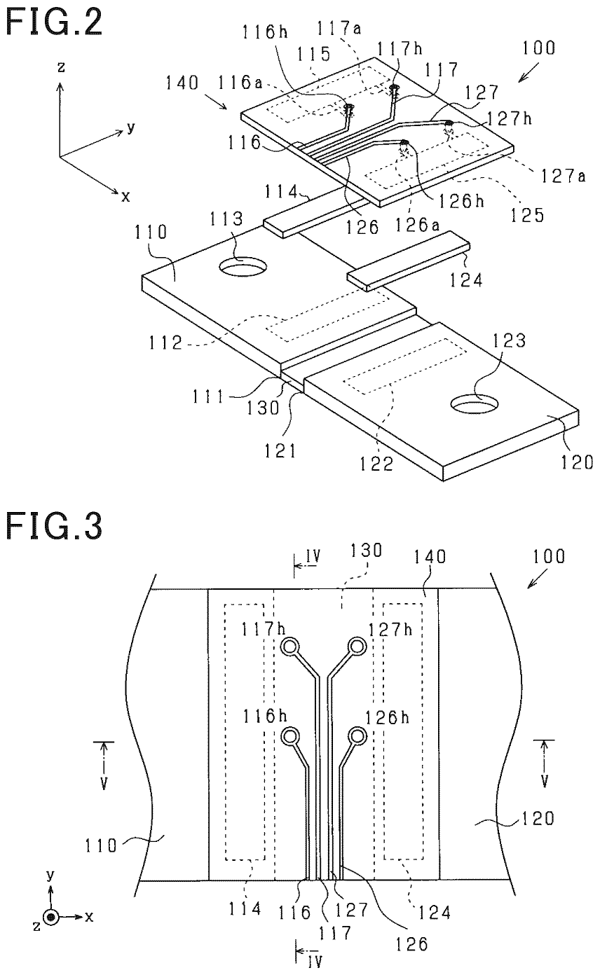

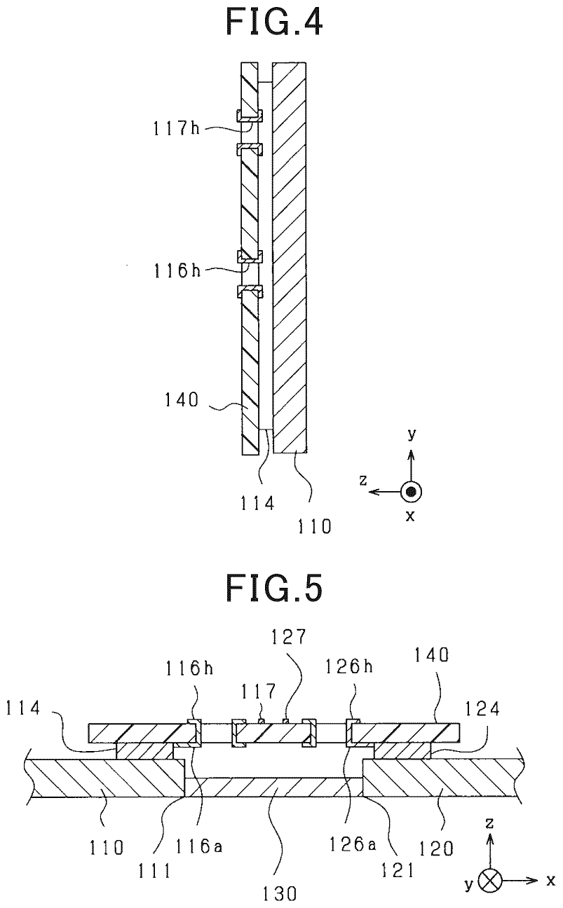

Each of FIGS. 2 to 5 shows a shunt resistor device 100 used as the resistor device 13 shown in FIG. 1. FIG. 2 is an exploded perspective view of the shunt resistor device 100, FIG. 3 is an upper surface diagram of the shunt resistor device 100, and FIGS. 4 and 5 are cross-sectional views of the shunt resistor device 100.

The shunt resistor device 100 includes a first electrode 110 and a second electrode 120, both of which are plate-shaped, a resistor 130, which is also plate-shaped, and a substrate 140.

The material of the resistor 130 includes, for example, nickel-chromium alloys, copper-nickel alloys, copper-manganese alloys, copper-manganese-nickel alloys, etc., but is not limited to these. The first electrode 110 and the second electrode 120 are busbars made of materials such as copper but are not limited to these. A first through hole 113 is formed in the first electrode 110 and a second through hole 123 is formed in the second electrode 120. The substrate 140 is a printed substrate, which may be a rigid substrate impregnated with an epoxy resin, etc., into glass, etc., or a flexible substrate made of a polyimide resin, etc. Wiring patterns are provided on the upper surface (the surface on the positive side of the z-axis) and lower surface (the surface on the negative side of the z-axis) of the substrate 140.

The first electrode 110 and the second electrode 120 are connected to respective ends of resistor 130 with respect to a first direction (the x-axis direction shown in FIG. 2) along the plate surface of the resistor 130. The positive z-axis surface of the first electrode 110 is joined to the negative z-axis surface of resistor 130, and the negative z-axis surface of the second electrode 120 is joined to the positive z-axis face of resistor 130. With respect to a second direction (the y-axis direction shown in FIG. 2) perpendicular to the first direction, the lengths of the first electrode 110, the second electrode 120, and resistor 130 are approximately the same. The first electrode 110, the second electrode 120, and resistor 130 are flat plates approximately parallel to the xy plane shown in FIG. 2. The thickness of each of the first electrode 110 and the second electrode 120 in a third direction (the z-axis direction shown in FIG. 2) perpendicular to the first and second directions is approximately the same. The thickness of the resistor 130 in the third direction is thinner than the thickness of each of the first electrode 110 and the second electrode 120.

The first electrode 110, the second electrode 120, and resistor 130 are aligned in the positive and negative directions of the y-axis and in the negative direction of the z-axis and are joined by welding. The first electrode 110 and the resistor 130 are joined to each other by a first weld 111, and the second electrode 120 and the resistor 130 are joined to each other by a second weld 121. The first weld 111 and the second weld 121 are examples of a “conductive joint”. The first electrode 110 and the resistor 130 are joined to each other by the first weld 111 and are electrically connected. The second electrode 120 and resistor 130 are joined to each other by the second weld 121 and are electrically connected.

In an upper surface of the substrate 140, a pair of first upper surface wiring 116, 126 and a pair of second upper surface wiring 117, 127 are provided. In a lower surface of the substrate 140, a first joint wiring 115 and a second joint wiring 125 are provided.

In the upper surface of the substrate 140, a pair of a first detection points 116h, 126h are provided. In the lower surface of the substrate 140, a pair of second detection points 117h, 127h are provided. Each of the first detection points 116h, 126h and the second detection points 117h, 127h is formed by wiring provided on the periphery and inner surface of a via hole that penetrates the substrate 140 in the vertical direction.

In the upper surface of substrate 140, the first detection points 116h, 126h are connected to the first upper surface wiring 116, 126, respectively, and the second detection points 117h, 127h are connected to the second upper surface wiring 117, 127, respectively. The first upper surface wiring 116 and 126 are connected to the first AD converter ADC 1 of the detection circuit 15, and the second upper surface wiring 117 and 127 are connected to the second AD converter ADC 2 of the detection circuit 15.

In lower surface of the substrate 140, the first detection points 116h, 117h are connected to the first joint wiring 115 via the first lower surface wiring 116a and the second lower surface wiring 117a, respectively, and the first detection point 126h and the second detection point 127h are connected to the second joint wiring 125 via the first lower surface wiring 126a and the second lower surface wiring 127a, respectively.

The first detection point 116h and the second detection point 117h are provided on the first electrode 110 side, and the first detection point 126h and the second detection point 127h are provided on the second electrode 120 side. The first detection points 116h, 126h are positioned approximately at the center of the y-axis direction of the first electrode 110 and the second electrode 120. The second detection points 117h, 127h are positioned at the end portion of the positive direction of the y-axis direction of the first electrode 110 and the second electrode 120. The second detection points 117h, 127h are located on the end side in the y-axis direction of the first electrode 110 and the second electrode 120 relative to the first detection points 116h, 126h. Each of the first upper surface wiring 116 and 126 extends from the negative end of the y-axis of the substrate 140 in the positive direction of the y-axis and has a shape that bends toward the first detection points 116h, 126h, respectively. Each of the second upper surface wiring 117, 127 extends from the negative end of the y-axis of the substrate 140 in the positive direction of the y-axis between the first upper surface wiring 116, 126, and has a shape that bends toward the second detection points 117h, 127h.

The substrate 140 is joined to the first electrode 110 by the first soldering 114 and to the second electrode 120 by the second soldering 124. The first soldering 114 is provided on the first soldering point 112 of the upper surface of the first electrode 110 and is soldered such that the first joint wiring 115 of the substrate 140 is positioned on the upper surface of the first soldering 114. The second soldering 124 is provided on the second soldering point 122 of the upper surface of the second electrode 120 and is soldered such that the second joint wiring 125 of the substrate 140 is positioned on the upper surface of the second soldering 124. Since the thickness of the resistor 130 in the z direction is thinner than the thickness of each of the first electrode 110 and the second electrode 120 and is aligned so that the surfaces in the negative direction of the z axis are aligned, as shown in FIG. 5, the distance between the upper surface of resistor 130 and the substrate 140 is wider than the distance between the upper surface of the first electrode 110 and the second electrode 120 and substrate 140. The first detection points 116h, 126h and the second detection points 117h, 127h are provided at positions above the resistor 130.

The first soldering 114 and the second soldering 124 are other examples of “conductive joint”. The first electrode 110 and substrate 140 are joined to each other by the first soldering 114. The first joint wiring 115 of the first electrode 110 and the substrate 140 are electrically connected by the first soldering 114. The second electrode 120 and the substrate 140 are joined to each other by the second soldering 124. The second joint wiring 125 of the second electrode 120 and substrate 140 are electrically connected to each other by the second soldering 124.

The shunt resistor device 100 can be manufactured, for example, by the following steps.

(1) Preparing the first electrode 110, the second electrode 120, and the resistor 130, and weld them together.

(2) Forming the first soldering 114 on the first soldering point 112 and form the second soldering 124 on the second soldering 122.

(3) Preparing substrate 140 with a wiring pattern formed, align substrate 140 so that the first joint wiring 115 is positioned at the upper surface of the first soldering 114 and the second joint wiring 125 is positioned at the upper surface of the second soldering 124, and solder them.

This enables the manufacture of shunt resistor device 100.

The first AD converter ADC1 is connected to the first upper surface wiring 116 and 126 and detects the terminal voltage between the first electrode 110 and the second electrode 120 as the first voltage V1. The current path from the first upper surface wiring 116 to the first upper surface wiring 126 (first current path) passes through the first upper surface wiring 116, the first detection point 116h (more specifically, from the upper surface side to the lower surface side of the first detection point 116h), the first lower surface wiring 116a, the first joint wiring 115, the first soldering 114, the first electrode 110, the first weld 111, the resistor 130, the second weld 121, the second electrode 120, the second soldering 124, the second joint wiring 125, the first lower surface wiring 126a, the first detection point 126h (more specifically, from the lower surface side to the upper surface side of the first detection point 126h), and the first upper surface wiring 126, in this order. Since the first detection points 116h, 126h are located approximately at the center of the y-axis direction of the first electrode 110 and the second electrode 120 respectively, the first current path passes through a path approximately at the center of the y-axis direction of the resistor 130.

The second AD converter ADC2 is connected to the second upper surface wiring 117 and 127 and detects the terminal voltage between the first electrode 110 and the second electrode 120 as the second voltage V2. The current path from the second upper surface wiring 117 to the second upper surface wiring 127 (the second current path) passes through the second upper surface wiring 117, the second detection point 117h (more specifically, from the upper surface side to the lower surface side of the second detection point 117h), the second lower surface wiring 117a, the first joint wiring 115, the first soldering 114, the first electrode 110, the first weld 111, the resistor 130, the second weld 121, the second electrode 120, the second soldering 124, the second joint wiring 125, the second lower surface wiring 127a, the second detection point 127h (more specifically, from the lower surface side to the upper surface side of Second detection point 127h), and the second upper surface wiring 127 in this order. Since the second detection points 117h, 127h are located on the positive end side of the y-axis direction in the first electrode 110 and the second electrode 120 respectively, the second current path passes through the positive end side of the y-axis direction of the resistor 130.

The monitoring device 20 includes a fault detection unit 21, a correction unit 22, and a control unit 23. The monitoring device 20 is mainly composed of a microcomputer (microcontroller) including a CPU, ROM, RAM, a flash memory, etc. For example, by executing a power conversion program installed in the ROM, the CPU may realize the functions of the fault detection unit 21, the correction unit 22, and the control unit 23 of the monitoring device 20. The functions provided by the microcomputer may be provided by software recorded in a physical memory device and a computer that executes it, software alone, hardware alone, or a combination thereof. For example, when the microcomputer is provided by electronic circuits as hardware, it may be provided by digital circuits containing multiple logic circuits or analog circuits. For example, the microcomputer executes a program stored in a non-volatile physical recording medium serving as its memory. The program includes, for example, a battery control processing program described below. When the program is executed, the corresponding method is executed. The memory unit may be, for example, a non-volatile memory. Note that the program stored in the memory unit may be updated via a network such as the Internet.

The fault detection unit 21 determines whether the first weld 111, the second weld 121, the first soldering 114, and the second soldering 124 are in a joint abnormality state based on the detection voltages of the first detection points 116h, 126h, and second detection points 117h, 127h.

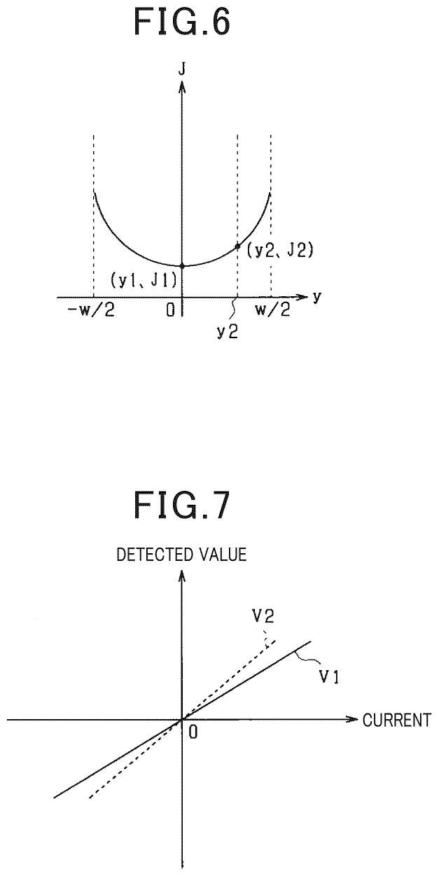

FIG. 6 is a diagram showing a current density distribution of the current flowing through the first electrode 110, the second electrode 120, and the resistor 130 in the shunt resistor device 100. The vertical axis indicates the current density J, and the horizontal axis indicates a position in the y-axis direction of the first electrode 110 and the second electrode 120. In FIG. 6, w is the length of the first electrode 110 and the second electrode 120 in the y-axis direction, y=0 indicates the central position of the first electrode 110 and the second electrode 120 in the y-axis direction, y=−w/2 indicates the end position in the negative y-axis direction of the first electrode 110 and the second electrode 120, and y=w/2 indicates the end position in the positive y-axis direction of the first electrode 110 and the second electrode 120. As shown in FIG. 6, the current density of the positive current flowing through the shunt resistor device 100 forms a downwardly convex curved distribution, being lower near the center of the first electrode 110 and the second electrode 120 and increasing toward the ends.

As shown in FIG. 6, the first detection points 116h, 126h are located at y=y1, which is approximately the center in the y-axis of the first electrode 110 and the second electrode 120 respectively, and the current density at this position is J1. The second detection points 117h, 127h are located at y=y2, which is the end portion in the positive y-axis direction of the first electrode 110 and second electrode 120 respectively, and the current density at this position is J2. Since J1 is lower than J2, even if the current flowing through the first electrode 110, the second electrode 120, and the resistor 130 is the same, the first voltage V1 detected by the first AD converter ADC1 is lower than the second voltage V2 detected by the second AD converter ADC2.

FIG. 7 is a graph showing the current flowing through the first electrode 110, second electrode 120, and the resistor 130 on the horizontal axis and the voltage detection values detected by the first and second AD converter ADC 1 and ADC 2 on the vertical axis. Even if the current flowing through the first electrode 110, the second electrode 120, and the resistor 130 is the same, the absolute value of the first voltage V1 detected by the first AD converter ADC1 is smaller than the absolute value of the second voltage V2 detected by the second AD converter ADC2.

When there is no joint abnormality in each conductive joint, as shown in FIG. 7, for a given current, the first voltage V1 and the second voltage V2 differ by a predetermined voltage difference. However, due to thermal history such as heat generation caused by the current flowing through the shunt resistor device 100, joint abnormalities may occur in each conductive joint. Joint abnormalities are more likely to occur at positions with higher current density than at positions with lower current density for the same current. In other words, joint abnormalities are more likely to occur at the y-axis end portion of each of the first electrode 110 and second electrode 120, which have higher current density, than at the y-axis central portion of each of the first electrode 110 and second electrode 120, which have lower current density. The joint abnormalities that occur at the y-axis end portions of the first electrode 110 and the second electrode 120 gradually spread toward the central portion.

In the positive direction of the y-axis at the end portion of the first electrode 110 and the second electrode 120, when the joint abnormality occurs in any of the conductive joints, and this joint abnormality gradually progresses toward the center, in the resistor 130, the second current path including the second detection points 117h, 127h approaches the first current path including the first detection points 116h, 126h. 126h. As a result, the second voltage V2 gradually approaches the first voltage V1, and the difference between them becomes smaller.

Therefore, the fault detection unit 21 determines that the joint abnormality has occurred in any of the conductive joints of the shunt resistor device 100 when a change occurs in the difference between the first voltage V1 and the second voltage V2. For example, the fault detection unit 21 may determine that the joint abnormality has occurred when the absolute value of the difference between the first voltage V1 and the second voltage V2, abs(V1−V2), is equal to or less than a predetermined threshold voltage difference Vth (when abs(V1−V2)≤Vth). The threshold voltage difference Vth is set such that 0≤Vth≤Vr, where Vr is the absolute value of the difference between the first voltage V1 and the second voltage V2 when there are no joint abnormalities in each conductive joint of the shunt resistor device 100. The value of V_r may be theoretically calculated based on the design value of the shunt resistor device 100, or it may be calculated using the first voltage V1 and the second voltage V1 measured using the shunt resistor device 100 in its initial state.

The correction unit 22 corrects at least one of the first voltage V1 and the second voltage V2 so that the first voltage V1 and the second voltage V2 are approximately the same. The correction unit 22 may, for example, use the difference or ratio between the second voltage V2 and the first voltage V1 to correct the first voltage V1 and the second voltage V2 so that they are approximately the same. The correction unit 22 may correct the first voltage V1, but since the second voltage V2 is a value that changes when a joint abnormality occurs in each conductive joint, while the first voltage V1 is a value that does not change easily even when a joint abnormality occurs in each conductive joint, it is preferable to correct the second voltage V2.

The correction unit 22 may correct the first voltage V1 and the second voltage V2 so that they become approximately the same when the fault detection unit 21 determines that a joint abnormality has occurred. By comparing the first voltage V1 and the second voltage V2 in the corrected state, it is possible to determine, for example, whether the first AD converter ADC1 and the second AD converter ADC2 are faulty. The fault detection unit 21 may also be capable of detecting faults in the first AD converter ADC1 and the second AD converter ADC2.

Alternatively, after the correction unit 22 corrects the first voltage V1 and the second voltage V2 so that they are approximately equal, the fault detection unit 21 may compare the first voltage V1 and the second voltage V2 in the corrected state and determine that there is a joint abnormality. For example, when the second voltage V2 is corrected to the corrected value V2a, the fault detection unit 21 may determine that the joint abnormality occurs when the absolute value of the difference between the first voltage V1 and the corrected value V2a, abs(V1−V2a), is equal to or greater than a predetermined threshold voltage difference Vtha (abs(V1−V2a)≥Vtha).

The control unit 23 performs control to open or close the first relay RL1 and the second relay RL2 based on at least one of the first voltage V1 and the second voltage V2 acquired from the detection circuit 15. The control unit 23 performs control to interrupt the current flowing through the shunt resistor device 100 when the joint abnormality is detected by the fault detection unit 21. For example, when the fault detection unit 21 detects a fault such as the joint abnormality in the shunt resistor device 100, the control unit 23 interrupts the current flowing through the shunt resistor device 100 by controlling the first relay RL1 and the second relay RL2 to the open state. Furthermore, if the power supply system 10 has a configuration capable of limiting the current flowing through the shunt resistor device 100, the control unit 23 may determine whether to limit or interrupt the current flowing through the shunt resistor device 100 when the fault detection unit 21 determines that the joint abnormality has occurred and execute either control.

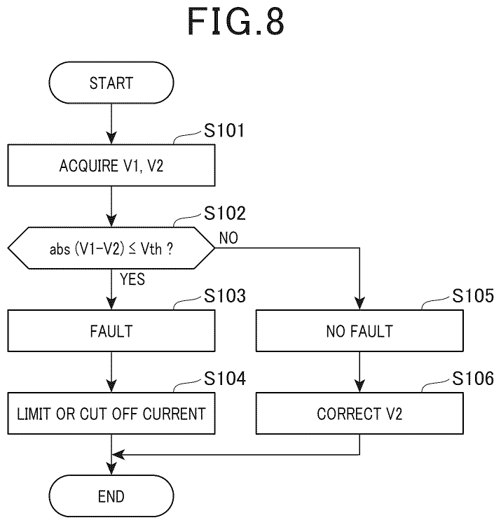

FIG. 8 is a flowchart of the monitoring process for the shunt resistor device 100 performed by the monitoring device 20. The process shown in the flowchart of FIG. 8 is realized by executing a monitoring program installed in the ROM by the CPU constituting the monitoring device 20 and is repeatedly performed at predetermined intervals during the charging and discharging of the battery 11.

In step S101, the monitoring device 20 acquires the first voltage V1 and the second voltage V2 and proceeds to step S102. In step S102, the monitoring device 20 determines whether the absolute value of the difference between the first voltage V1 and the second voltage V2 (abs(V1−V2)) is equal to or less than the threshold voltage difference Vth (abs(V1−V2)≤Vth). When it is determined that the absolute value of the difference between the first voltage V1 and the second voltage V2 (abs(V1−V2)) is equal to or less than the threshold voltage difference Vth, the monitoring device 20 proceeds to step S103 and determines that the joint abnormality has occurred. When it is determined that the absolute value of the difference between the first voltage V1 and the second voltage V2 (abs(V1−V2)) is greater than the threshold voltage difference Vth, the monitoring device 20 proceeds to step S105 and determines that there is no joint abnormality.

In step S103, the monitoring device 20 determines that there is a fault in the shunt resistor device 100 and proceeds to step S104, where it limits or cuts off the current. The monitoring device 20 controls the first relay RL1 and the second relay RL2 to the open state and terminates the process.

In step S105, the monitoring device 20 determines that there is no failure in the shunt resistor device 100, proceeds to step S106, corrects the second voltage V2, and terminates the process.

As described above, according to the shunt resistor device 100 according to the first embodiment, in the substrate 140, the second detection points 117h, 127h are located on the end side of each electrode in the second direction relative to the first detection points 116h, 126h. That is, the second detection points 117h, 127h are located on the end side where the current density of the current flowing through the first electrode 110, the second electrode 120, and the resistor 130 is higher than that of the first detection points 116h, 126h. Therefore, when there is no joint abnormality in conductive joint in the shunt resistor device 100, the first voltage V1, which is the detection voltage acquired by the monitoring device 20 at the first detection points 116h, 126h, differs from the second voltage V2, which is the detection voltage acquired at the second detection points 117h, 127h. When the joint abnormality occurs in conductive joint in the shunt resistor device 100, the difference between the first voltage V1 and the second voltage V2 becomes smaller. The monitoring device 20 performs the fault determination steps shown in steps S102, S103, and S105, and determines that there is the joint abnormality in conductive joint in the shunt resistor device 100 when the absolute value of the difference between the first voltage V1 and the second voltage V2, abs(V1−V2), is less than or equal to Vth. According to the fault determination step, it is possible to monitor the joint abnormality of the shunt resistor device 100. Furthermore, in the fault determination step, when the shunt resistor device 100 is determined to be fault-free, the correction step shown in step S106 is performed, and the second voltage V2 is corrected to a correction value V2a that is approximately the same as the first voltage V1. Although not shown, by comparing the first voltage V1 and the corrected value V2a, it is also possible to determine, for example, whether the first AD converter ADC1 and the second AD converter ADC2 are faulty.

### (Variation)

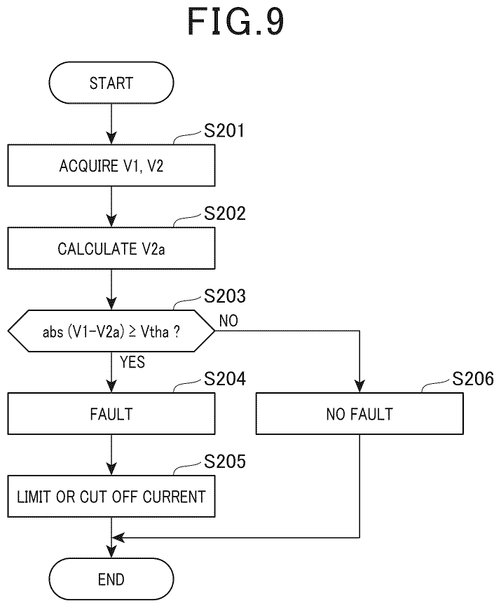

The monitoring device 20 may perform the process shown in the flowchart of FIG. 9 as a monitoring process for the shunt resistor device 100. The process shown in the flowchart of FIG. 9 is realized by executing a monitoring program installed in the ROM by the CPU constituting the monitoring device 20, and is repeatedly performed at predetermined intervals during the charging and discharging of the battery 11.

In step S201, the monitoring device 20 acquires the first voltage V1 and the second voltage V2 and proceeds to step S202. In step S202, the monitoring device 20 corrects the second voltage V2 acquired in step S201 to the corrected value V2a and proceeds to step S203. In step S203, the monitoring device 20 determines whether abs(V1−V2a)≤Vth. When it is determined that abs(V1−V2a)≤Vth, the monitoring device 20 proceeds to step S204 and determines that there is the joint abnormality. When it is determined that abs(V1−V2a)>Vth, the monitoring device 20 proceeds to step S205 and determines that there is no joint abnormality.

In step S204, the monitoring device 20 determines that shunt resistor device 100 is faulty and proceeds to step S205 to limit or interrupt the supply current. As a result, the monitoring device 20 controls the first relay RL1 and the second relay RL2 to the open state and terminates the processing. In step S206, it is determined that there is no fault in shunt resistor device 100, and the process is terminated.

### Second Embodiment

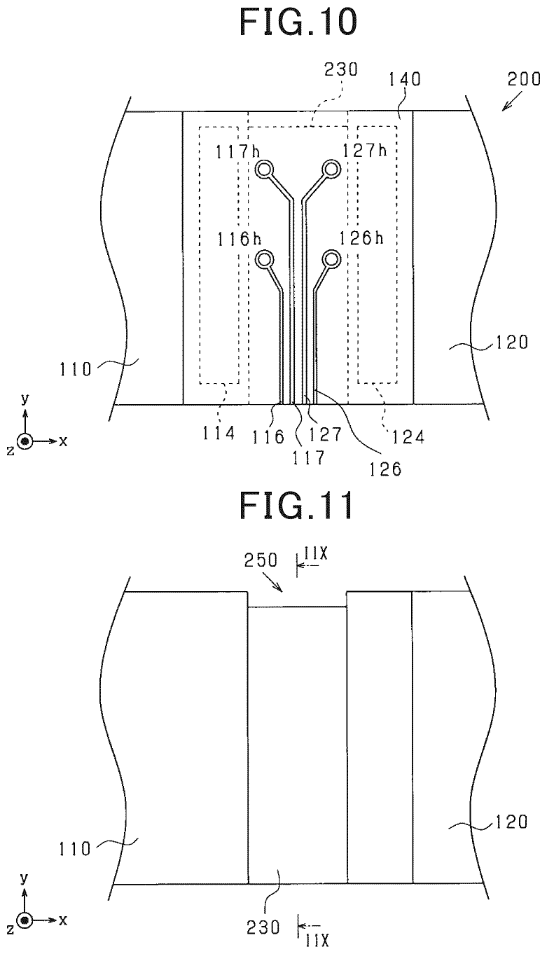

FIG. 10 shows a shunt resistor device 200 according to the second embodiment. The shunt resistor device 200 is used as the resistor device 13 shown in FIG. 1, like the first embodiment. The shunt resistor device 200 differs from the shunt resistor device 100 shown in FIG. 2, etc., in the form of a resistor 230. In the shunt resistor device 200, the same reference symbols are used for the same configurations as in shunt resistor device 100.

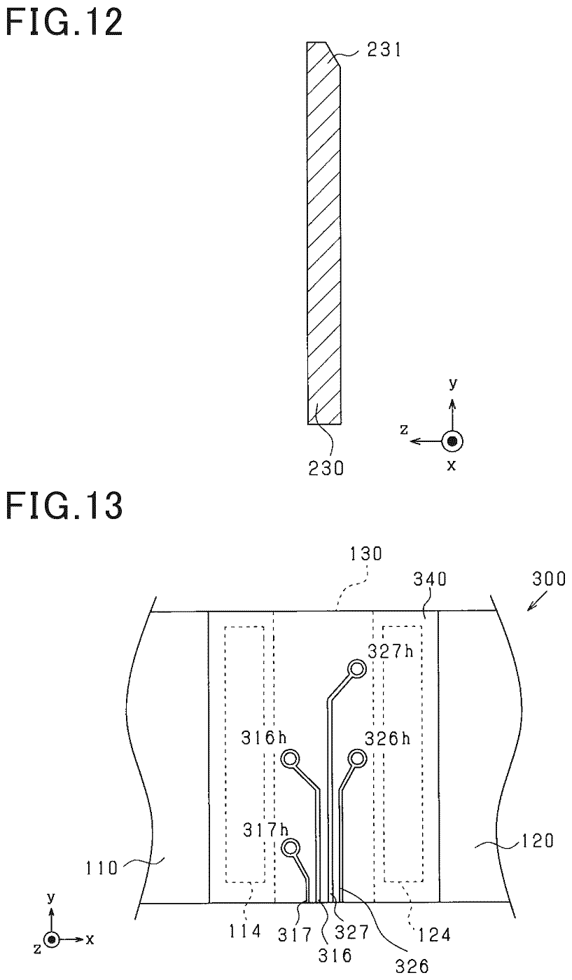

FIG. 11 shows the state of shunt resistor device 200 in which the substrate 140, the first soldering 114 and the second soldering 124 are removed. The first electrode 110 and the second electrode 120 are welded to respective ends of the resistor 230 respectively. FIG. 12 is a cross-sectional view of the resistor 230 shown in FIG. 11. As shown in FIGS. 10 and 11, the length of the resistor 230 in the y-axis direction is shorter than the length of each of the first electrode 110 and the second electrode 120 in the y-axis direction. The resistor 230 and the first electrode 110 and the second electrode 120 are connected such that the ends on the negative side of the y-axis are aligned, and a cavity 250, where the resistor 230 does not exist between the first electrode 110 and the second electrode 120, is formed on the positive side of the y-axis. Furthermore, as shown in FIG. 12, the resistor 230 is locally thinned at the end in the positive direction of the y-axis. The cross-sectional area perpendicular to the x-axis of this thinned portion is reduced compared to the cross-sectional area perpendicular to the x-axis of the non-thinned portion and is referred to as a restriction part 231.

The resistor 230 has the restriction part 231 in which the length (thickness) in the z-axis direction is reduced at the end portion in the positive direction of the y-axis, and, resulting in a reduced cross-sectional area perpendicular to the x-axis compared to the end portion in the negative direction of the y-axis. The x-axis direction is the direction of the current flowing through the first electrode 110, the second electrode 120, and the resistor 230. Therefore, due to the reduction in the cross-sectional area perpendicular to the x-axis, the current density in the restriction part 231, which is provided on the positive end side of the y-axis, is higher than the current density on the negative end side of the y-axis in the resistor 230. Therefore, any joint abnormalities in the conductive joints of the shunt resistor device 200 are more likely to occur in the side having the restriction part 231, which has a higher current density. In the shunt resistor device 200, while the second detection points 117h, 127h is provided on the substrate 140 located at the y-axis positive end of upper surface where the restriction part 231 is provided in the resistor 230, while the second detection point is not provided on the substrate 140 located at the upper surface on the y-axis negative end side where the restriction part is not provided. By setting the second detection points 117h, 127h only on the upper surface side of the restriction part 231, where joint abnormalities in each conductive joint of the shunt resistor device 200 are most likely to occur, it is possible to suppress the number of detection points installed and ensure that joint abnormalities in each conductive joint of the shunt resistor device 200 is reliably detected.

### Third Embodiment

FIG. 13 shows a shunt resistor device 300 according to a third embodiment. The shunt resistor device 300 is used in the same manner as the resistor device 13 shown in FIG. 1 according to the first embodiment. The shunt resistor device 300 differs from the shunt resistor device 100 shown in FIG. 2, etc., in the form of the wiring pattern provided in a substrate 340. In the shunt resistor device 300, the same reference symbols are used for configurations identical to those of the shunt resistor device 100.

A pair of first detection points 316h, 326h and a pair of second detection points 317h, 327h are provided in the upper surface and lower surface of substrate 340 respectively. Each of the first detection points 316h, 326h and the second detection points 317h, 327h is formed by wiring provided around the periphery and inner surface of a via hole that penetrates the substrate 340 in the vertical direction.

The first detection points 316h, 326h are positioned at the same locations as the first detection points 116h, 126h in the shunt resistor device 100. The second detection point 327h is positioned at the same location as the second detection point 127h in the shunt resistor device 100, while the second detection point 317h is positioned on the negative y-axis side relative to the first detection point 316h, unlike the second detection point 117h in the shunt resistor device 100. First upper surface wirings 316 and 326 are connected to the first detection points 316h, 326h, respectively, and second upper surface wirings 117 and 127 are connected to the second detection points 317h, 327h, respectively.

The second detection point 317h is a detection point near the first end portion, which is the positive end of the y-axis on the first electrode 110 side, and the second detection point 327h is a detection point located near the second end portion, which is the negative y-axis end portion opposite the first end portion on the second electrode 120 side. While the first detection points 316h, 326h are arranged in a straight line along the x-axis direction, the second detection points 317h, 327h are arranged approximately diagonally with respect to the resistor 230. Since the second detection points 317h, 327h are provided on the first end portion side and the second end portion side, respectively, even if a joint abnormality occurs in any of the conductive joints of the shunt resistor device 300, the value of the second voltage V2 gradually approaches the value of the first voltage V1, and the difference between them becomes smaller, enabling detection of the joint abnormality. According to shunt resistor device 300, it is possible to suppress the number of voltage detection points and reliably detect joint abnormalities in each conductive joint of shunt resistor device 300.

### Fourth Embodiment

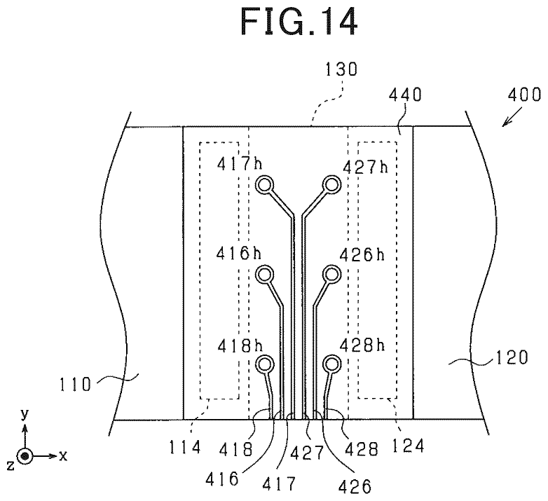

FIG. 14 shows a shunt resistor device 400 according to a fourth embodiment. The shunt resistor device 400 differs from the shunt resistor device 100 shown in FIG. 2, etc., in the form of the wiring pattern provided in a substrate 440. In the shunt resistor device 400, the same reference symbols are used for the same configurations as in the shunt resistor device 100.

A pair of first detection points 416h, 426h, a pair of second detection points 417h, 427h, and a pair of second detection points 418h, 428h are provided in the upper surface and lower surface of the substrate 440, respectively. Each of the first detection points 416h, 426h, the second detection points 417h, 427h, and the second detection points 418h, 428h is formed by wiring provided around the periphery and inner surfaces of a via hole that penetrates the substrate 440 in the vertical direction.

The first detection points 416h, 426h are positioned in the same locations as the first detection points 116h, 126h in the shunt resistor device 100. The second detection points 417h and 427h are positioned at the same location as the second detection points 117h, 127h in the shunt resistor device 100. The second detection points 418h, 428h are positioned on the negative y-axis side of the first electrode 110 and the second electrode 120, respectively. The distance between each of the second detection points 418h, 428h and the negative end of the y-axis direction in the first electrode 110 and second electrode 120, respectively is approximately the same as the distance between each of the second detection points 117h, 127h and the positive end of the y-axis direction in the first electrode 110 and second electrode 120, respectively. The first upper surface wiring 416 and 426 are respectively connected to the first detection points 416h, 426h, the second upper surface wiring 417 and 427 are respectively connected to the second detection points 417h and 427h, and the second upper surface wiring 418 and 428 are respectively connected to the second detection points 418h, 428h.

The shunt resistor device 400 is used as the resistor device 13 shown in FIG. 1, as in the first embodiment. When the shunt resistor device 400 is used as the resistor device 13, the detection circuit 15 further includes a third AD converter ADC3. The third AD converter ADC3 is connected to the first upper surface wiring 418 and the first upper surface wiring 428, and detects the terminal voltage between the first electrode 110 and the second electrode 120 in the resistor 130 of the shunt resistor device 400 as the third voltage V3.

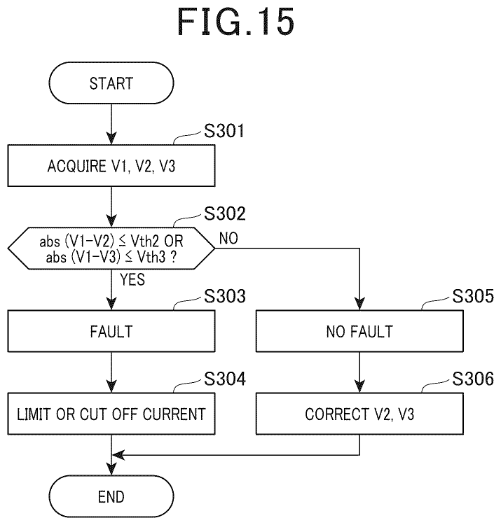

FIG. 15 is a flowchart of the monitoring process performed by the monitoring device 20 for the shunt resistor device 400. The process shown in the flowchart of FIG. 15 is realized by executing the monitoring program installed in the ROM by the CPU constituting monitoring device 20 and is repeatedly performed at predetermined intervals during the charging and discharging of the battery 11.

In step S301, the monitoring device 20 acquires the first voltage V1, the second voltage V2, and the third voltage V3, and proceeds to step S302. In step S302, the monitoring device 20 determines whether abs(V1−V2)≤Vth2 or abs(V1−V3)≤Vth3 for predetermined threshold voltage differences Vth2 and Vth3. When abs(V1−V2)≤Vth2 or abs(V1-V3)≤Vth3, the monitoring device 20 proceeds to step S303. When abs(V1−V2)>Vth2 and abs(V1−V3)>Vth3, the monitoring device 20 proceeds to step S305 and determines that there is no joint abnormality. The threshold voltage differences Vth2 and Vth3 is set using the same method as for the threshold voltage difference Vth in the first embodiment.

In step S303, the monitoring device 20 determines that there is a fault in the shunt resistor device 400, proceeds to step S404, and limits or interrupts the supply current. As a result, the monitoring device 20 controls the first relay RL1 and the second relay RL2 to the open state and terminates the processing.

In step S305, the monitoring device 20 determines that there is no fault in shunt resistor device 400, proceeds to step S406, corrects the second voltage V2 and the third voltage V3, and terminates the process.

In the shunt resistor device 400, the second detection points 417h, 427h are provided on the positive end side of the y-axis direction in the first electrode 110 and the second electrode 120, respectively, and the second detection points 418h, 428h are provided on the negative end side of the y-axis direction in the first electrode 110 and the second electrode 120, respectively. Therefore, when a joint abnormality occurs in any of the conductive joints of the shunt resistor device 400 from the positive end of the y-axis direction, the value of the second voltage V2 gradually approaches the first voltage V1, and the difference becomes smaller, enabling detection of the joint abnormality. If the joint abnormalities of each conductive joint in the shunt resistor device 400 occur from the end portion on the negative side of the y-axis direction, the value of the third voltage V3 gradually approaches the first voltage V1, and the difference becomes smaller, enabling detection of the occurrence of bonding abnormalities.

Additionally, the resistor of the shunt resistor device 400 may have the same configuration as restriction part 231 according to the third embodiment. The restriction part 231 may be provided on the positive and negative ends of the y-axis in the first electrode 110 and second electrode 120, respectively. By providing the restriction part 231 to increase the current density, changes in the detection voltage at the second detection point located at the upper surface position is detected with high sensitivity.

In each of the above embodiments, the first and second soldering 114, 124 extend continuously from one end to the other end of the y-axis direction of the first electrode 110 and the second electrode 120, respectively. However, they may be divided into multiple segments. When the soldering is configured to be divided into multiple sections, it is preferable to configure the first and second soldering 114, 124 such that soldering is provided at the ends in the positive and negative directions of the y-axis. Additionally, if the first through hole 113 is provided at the approximate center of the y-axis direction of the first electrode 110 and the second through hole 123 is provided at the approximate center of the y-axis direction of the second electrode 120, the current density in the second detection point increases, enabling more sensitive detection of changes in the detection voltage in the second detection point. However, the first through hole 113 and the second through hole 123 may be omitted. Furthermore, although the embodiment described above illustrates a case where the control unit 23 limits or interrupts the current flowing through the shunt resistor device based on a determination that there is a joint abnormality in each conductive joint of the shunt resistor device 400, this is not limited to this example. When fault detection unit 21 determines that there is a joint abnormality in each conductive joint of shunt resistor device 400, the current flowing through shunt resistor device may be immediately cut off without any software judgment.

The control unit and method described in this disclosure may be provided by a dedicated computer configured with a processor and memory programmed to execute one or more functions specified by a computer program. Alternatively, the control unit and method described in this disclosure may be provided by a dedicated computer configured with one or more dedicated hardware logic circuits that constitute a processor. Alternatively, the control unit and method described herein may be implemented by one or more dedicated computers configured by a combination of a processor and memory programmed to execute one or more functions, and one or more hardware logic circuits. Furthermore, the computer program may be stored on a computer-readable non-transitory tangible medium as instructions executable by a computer.

The following describes the characteristic configurations extracted from each of the above-described embodiments.

### [Configuration 1]

A monitoring device (20) for a shunt resistor device (100, 200, 300, 400), the shunt resistor device including:
a plate-shaped resistor (130, 230);
a first electrode (110) and a second electrode (120) connected to respective ends of the resistor respectively in the first direction along the plate surface of the resistor; and
a substrate (140, 340, 440) having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint (111, 121, 114, 124) along a second direction orthogonal to the first direction,
the monitoring device measures a terminal voltage between the first electrode side and the second electrode side of the resistor based on the detection voltage between the pair of voltage detection point,
the substrate includes, as the pairs of voltage detection points, first detection points and second detection points, the second detection points being positioned on the end side of each electrode relative to the first detection points in the second direction, and
the monitoring device comprises an fault detection unit (21) that determines whether a joint abnormality of the conductive joint occurs based on the detection voltages of the first detection points and the second detection points.

### [Configuration 2]

The monitoring device for the shunt resistor device according to configuration 1, wherein
in the shunt resistor device, a restriction part (231) is provided at the end of the second direction where the resistor is not present between the first electrode and the second electrode, or where the resistor is locally thinned, and
the substrate includes the second detection points provided near the restriction part.

### [Configuration 3]

The monitoring device for the shunt resistor device according to configuration 2, wherein
the restriction part is provided only on one end side of the two ends in the second direction,
the substrate includes the second detection points only near the end of the second direction on the side of the restriction part.

### [Configuration 4]

The monitoring device for the shunt resistor device according to configuration 1, wherein
the second detection points include a detection point located near the first end of the second direction on the first electrode side, and a detection point located near the second end of the second direction on the opposite side of the first end.

### [Configuration 5]

The monitoring device for the shunt resistor device according to configuration 1, wherein
in the substrate, the second detection points are provided on respective ends of the first detection points in the second direction.

### [Configuration 6]

The monitoring device for the shunt resistor device according to any one of configuration 1 to 3, further including
a correction unit (22) that corrects at least one of the detection voltages of the first detection points and the detection voltage of the second detection points so that the detection voltage of the first detection points and the detection voltage of the second detection points are approximately the same.

### [Configuration 7]

A monitoring program for a shunt resistor device (100, 200, 300, 400), the shunt resistor device comprising:
a plate-shaped resistor (130, 230);
a first electrode (110) and a second electrode (120) connected to respective ends of the resistor respectively in the first direction along the plate surface of the resistor; and
a substrate (140, 340, 440) having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint (111, 121, 114, 124) along a second direction orthogonal to the first direction,
the substrate includes, as the pairs of voltage detection points, first detection points and second detection points, the second detection points being positioned on the end side of each electrode relative to the first detection points in the second direction,
the monitoring program causes a computer to perform:
a detection step for measuring a terminal voltage between the first electrode side and the second electrode side of the resistor based on the detection voltage between the pair of voltage detection points; and
a fault detection step for determining whether a joint abnormality of the conductive joint occurs based on the detection voltages of the first detection points and the second detection points.

### [Configuration 8]

A shunt resistor device (100, 200, 300, 400) comprising:
a plate-shaped resistor (130, 230);
a first electrode (110) and a second electrode (120) connected to respective ends of the resistor respectively in the first direction along the plate surface of the resistor; and
a substrate (140, 340, 440) having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint (111, 121, 114, 124) along a second direction orthogonal to the first direction, and
the substrate includes, as the pairs of voltage detection points, first detection points and second detection points, the second detection points being positioned on the end side of each electrode relative to the first detection points in the second direction.

The present disclosure has been described in accordance with the embodiments, but the present disclosure is not limited to the embodiments or structures described herein. The present disclosure includes various modifications and modifications within the scope of the equivalent range. In addition, various combinations and forms, as well as other combinations and forms including only one element, more than one element, or less than one element of the above, are also included within the scope and spirit of the present disclosure.

What is claimed is:

1. A monitoring device for a shunt resistor device, the shunt resistor device comprising:
a plate-shaped resistor;
a first electrode and a second electrode connected to respective ends of the resistor respectively in the first direction along the plate surface of the resistor; and
a substrate having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint along a second direction orthogonal to the first direction,
the monitoring device measures a terminal voltage between the first electrode side and the second electrode side of the resistor based on the detection voltage between the pair of voltage detection points,
the substrate includes, as the pairs of voltage detection points, first detection points and second detection points, the second detection points being positioned on the end side of each electrode relative to the first detection points in the second direction, and
the monitoring device comprises a fault detection unit that determines whether a joint abnormality of the conductive joint occurs based on the detection voltages of the first detection points and the second detection points.

2. The monitoring device for the shunt resistor device according to claim 1, wherein
in the shunt resistor device, a restriction part is provided at the end of the second direction where the resistor is not present between the first electrode and the second electrode, or where the resistor is locally thinned, and
the substrate includes the second detection points provided near the restriction part.

3. The monitoring device for the shunt resistor device according to claim 2, wherein
the restriction part is provided only on one end side of the two ends in the second direction,
the substrate includes the second detection points only near the end of the second direction on the side of the restriction part.

4. The monitoring device for the shunt resistor device according to claim 1, wherein
the second detection points include a detection point located near the first end of the second direction on the first electrode side, and a detection point located near the second end of the second direction on the opposite side of the first end.

5. The monitoring device for the shunt resistor device according to claim 1, wherein
in the substrate, the second detection points are provided on respective ends of the first detection points in the second direction.

6. The monitoring device for the shunt resistor device according to claim 1, further comprising
a correction unit that corrects at least one of the detection voltages of the first detection points and the detection voltage of the second detection points so that the detection voltage of the first detection points and the detection voltage of the second detection points are approximately the same.

7. A non-transitory computer-readable storage medium storing a monitoring program for a shunt resistor device, the shunt resistor device comprising:
a plate-shaped resistor;
a first electrode and a second electrode connected to respective ends of the resistor respectively in the first direction along the plate surface of the resistor; and
a substrate having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint along a second direction orthogonal to the first direction,
the substrate includes, as the pairs of voltage detection points, first detection points and second detection points, the second detection points being positioned on the end side of each electrode relative to the first detection points in the second direction,
the monitoring program causes a computer to perform:
a detection step for measuring a terminal voltage between the first electrode side and the second electrode side of the resistor based on the detection voltage between the pair of voltage detection points; and
a fault detection step for determining whether a joint abnormality of the conductive joint occurs based on the detection voltages of the first detection points and the second detection points.

8. A shunt resistor device comprising:
a plate-shaped resistor;
a first electrode and a second electrode connected to respective ends of the resistor respectively in the first direction along the plate surface of the resistor; and
a substrate having pairs of voltage detection points provided on the first electrode side and the second electrode side, respectively, and stacked on the resistor and each electrode,
wherein each of the space between the resistor and each electrode, and the space between each electrode and the substrate, is joined by a conductive joint along a second direction orthogonal to the first direction,
the substrate includes, as the pairs of voltage detection points, first detection points and second detection points, the second detection points being positioned on the end side of each electrode relative to the first detection points in the second direction,
in the shunt resistor device, a restriction part is provided at the end of the second direction where the resistor is not present between the first electrode and the second electrode, or where the resistor is locally thinned, and
the substrate includes the second detection points provided near the restriction part.
